(19) United States
(12) Patent Application Publication
(10) Pub. No.: US 2018/0261677 A1
(43) Pub. Date: Sep. 13, 2018

(54) Semiconductor Device and Method for Fabricating the Same

(71) Applicant: Samsung Electronics Co., Ltd., Suwon-si (KR)

(72) Inventors: Byoung Hoon LEE, Suwon-si (KR); Hyeon Jin KIM, Daegu (KR); Hoon Joo NA, Hwaseong-si (KR); Sung In SUH, Seoul (KR); Chan Hyeong LEE, Seoul (KR); Hu Yong LEE, Seoul (KR); Seong Hoon JEONG, Seongnam-si (KR); Sang Jin HYUN, Suwon-si (KR)

(21) Appl. No.: 15/653,588

(22) Filed: Jul. 19, 2017

(30) Foreign Application Priority Data
Mar. 7, 2017 (KR) 10-2017-0028654

(51) Int. Cl. H01L 29/49; H01L 29/78; H01L 27/092; H01L 21/28

(52) U.S. Cl. CPC H01L 29/4966; H01L 21/28008; H01L 27/092; H01L 29/785

(57) ABSTRACT

A semiconductor device includes a gate insulating layer disposed on a substrate, a first work function tuning layer disposed on the gate insulating layer, a lower barrier conductive layer on and in contact with the first work function tuning layer, and an upper barrier conductive layer on and in contact with the lower barrier conductive layer. The upper barrier conductive layer and the lower barrier conductive layer include a material in common, e.g., they may each include a titanium nitride (TiN) layer.

### CROSS REFERENCE TO RELATED APPLICATION

This application claims priority from Korean Patent Application No. 10-2017-0028654, filed on Mar. 7, 2017, in the Korean Intellectual Property Office, the disclosure of which is incorporated herein by reference in its entirety.

### BACKGROUND

### 1. Technical Field

The present inventive concept relates to a semiconductor device and a method for fabricating the same.

### 2. Description of Related Art

As information media rapidly prevail nowadays, the capability of semiconductor devices also drastically evolves. Recent semiconductor devices are required to be highly integrated for low cost and high quality to increase competitiveness. For high integration, semiconductor devices continue to be scaled down.

Research is ongoing to increase the operation speed and the integration degree of semiconductor devices. Semiconductor devices have discrete devices such as MOS transistors. As the semiconductor devices become highly integrated, the gate of a MOS transistor is getting smaller and the channel region under the gate is also becoming narrower.

### SUMMARY

Aspects of the present inventive concept provide a semiconductor device capable of improving operation performance and reliability by performing film treatment to reduce the resistance of a work function tuning layer.

Aspects of the present inventive concept also provide a method for fabricating a semiconductor device that improves operation performance and reliability by performing film treatment to reduce the resistance of a work function tuning layer.

It should be noted that objects of the present inventive concept are not limited to the above-described objects, and other objects of the present inventive concept will be apparent to those skilled in the art from the following descriptions.

According to aspects of the present inventive concept, there is provided a semiconductor device comprising a gate insulating layer disposed on a substrate, a first work function tuning layer disposed on the gate insulating layer, a lower barrier conductive layer disposed on the first work function tuning layer and being in contact with the first work function tuning layer, and an upper barrier conductive layer disposed on the lower barrier conductive layer and being in contact with the lower barrier conductive layer, wherein the upper barrier conductive layer comprises a same material with the lower barrier conductive layer.

According to aspects of the present inventive concept, there is provided a semiconductor device comprising an interlayer insulating layer disposed on a substrate and comprising a first trench and a second trench, an n-type first work function tuning layer extending along sidewalls and a bottom surface of the first trench, a first lower barrier conductive layer disposed on the first work function tuning layer and being in contact with the first work function tuning layer, a first upper barrier conductive layer disposed on the first lower barrier conductive layer and being in contact with the lower barrier conductive layer, wherein the first upper barrier conductive layer comprises a same material as the first lower barrier conductive layer, a second work function tuning layer extending along side walls and a bottom surface of the second trench, wherein the second work function tuning layer comprises a same material as the first work function tuning layer, and a second barrier conductive layer disposed on the second work function tuning layer and comprising a same material as the first lower barrier conductive layer, wherein a thickness of the second barrier conductive layer is greater than a thickness of the first lower barrier conductive layer and a thickness of the first upper barrier conductive layer.

According to aspects of the present inventive concept, there is provided a semiconductor device comprising a fin-shaped pattern protruding from a substrate, a field insulating layer disposed on the substrate and covering a part of a side wall of the fin-shaped pattern, a gate insulating layer formed along an upper surface of the field insulating layer and a profile of the fin-shaped pattern, a titanium aluminum carbide (TiAlC) layer formed on the gate insulating layer along the gate insulating layer, a first TiN layer disposed on the TiAlC layer and in contact with the TiAlC layer, and a second TiN layer disposed on the first TiN layer and in contact with the first TiN layer.

According to aspects of the present inventive concept, there is provided a method for fabricating a semiconductor device, the method comprising forming a gate insulating layer on a substrate, forming an n-type work function tuning layer on the gate insulating layer, forming a lower barrier conductive layer on the work function tuning layer, performing a film treatment process on the work function tuning layer after the forming the lower barrier conductive layer, and forming an upper barrier conductive layer on the lower barrier conductive layer after forming the film treatment process, wherein the upper barrier conductive layer comprises a same material with the lower barrier conductive layer.

### BRIEF DESCRIPTION OF THE DRAWINGS

The above and other aspects and features of the present inventive concept will become more apparent by describing in detail exemplary embodiments thereof with reference to the attached drawings, in which:

FIG. 1 is a diagram for illustrating a semiconductor device according to some exemplary embodiments of the present inventive concept;

FIGS. 2 to 5 are diagrams for illustrating a semiconductor device according to some exemplary embodiments of the present inventive concept, respectively;

FIG. 6 is a layout diagram for illustrating a semiconductor device according to some exemplary embodiments of the present inventive concept;

FIG. 7 is a cross-sectional view taken along line A-A of FIG. 6;

FIG. 8 is a cross-sectional view taken along line B-B of FIG. 6;

FIGS. 9 and 10 are diagrams for illustrating a semiconductor device according to some exemplary embodiments of the present inventive concept;

FIGS. 11 to 15 are diagrams for illustrating a semiconductor device according to some exemplary embodiments of the present inventive concept;

FIG. 16 is a layout diagram for illustrating a semiconductor device according to some exemplary embodiments of the present inventive concept;

FIG. 17 is a cross-sectional view taken along lines A-A and line C-C of FIG. 16;

FIG. 18 is a cross-sectional view taken along line B-B and line D-D of FIG. 16;

FIGS. 19 to 24 are cross-sectional views for illustrating processing steps of a method for fabricating a semiconductor device according to some exemplary embodiments of the present inventive concept; and

FIG. 25 is a diagram showing a processing step of the method according to some embodiments of the present inventive concept.

### DETAILED DESCRIPTION OF THE EMBODIMENTS

Although the drawings relating to the semiconductor devices according to some embodiments of the present inventive concept illustratively show a fin-type transistor (FinFET) including a channel region of a fin-shaped pattern, this is merely illustrative. It is to be understood that the semiconductor devices according to some embodiments of the present inventive concept may include a tunneling FET, a transistor including a nanowire, a transistor including a nanosheet, or a three-dimensional (3D) transistor. In addition, the semiconductor devices according to some embodiments of the present inventive concept may include a bipolar junction transistor, a lateral double diffusion transistor (LDMOS), and the like.

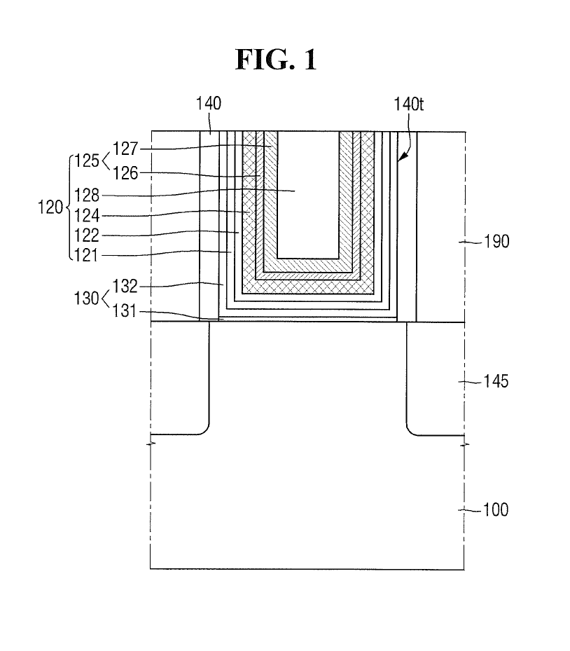

FIG. 1 is a diagram for illustrating a semiconductor device according to some exemplary embodiments of the present inventive concept. Isolation layers such as STI (shallow trench isolation) can be formed in the substrate.

Referring to FIG. 1, a semiconductor device according to some exemplary embodiments of the present inventive concept includes a first gate spacer 140, a first trench 140t, a first gate insulating layer 130, and a first gate electrode structure 120.

The first gate electrode structure 120 includes a first lower conductive layer 121, a first etch-stop conductive layer 122, a first n-type work function tuning layer 124, a first barrier conductive layer 125, and a first filling conductive layer 128. The first barrier conductive layer 125 may include a first lower barrier conductive layer 126 and a first upper barrier conductive layer 127.

A substrate 100 may be a bulk silicon substrate or a SOI (silicon-on-insulator) substrate. Alternatively, the substrate 100 may be a silicon substrate or may be a substrate made of materials including, but is not limited to, silicon germanium, silicon germanium on insulator (SGOI), indium antimonide (InSb), lead-telluride (PbTe) compound, indium arsenide (InAs), indium phosphide (InP), gallium arsenide (GaAs), and gallium antimonide (GaSb).

In the following description, it is assumed that the substrate 100 is a substrate comprising silicon, for convenience of illustration.

The first gate spacer 140 may be formed on the substrate 100. Although the first gate spacer 140 is shown as a single layer, this is illustrative. For example, the first gate spacer 140 may be formed as multiple layers.

The first gate spacer 140 may include, for example, at least one of silicon nitride (SiN), silicon oxynitride (SiON), silicon oxide (SiO₂), silicon oxycarbonitride (SiOCN), and a combination thereof.

If the first gate spacer 140 is formed as a plurality of layers, at least one of the layers may comprise a low-dielectric material such as silicon oxynitride (SiON). When the first gate spacer 140 is formed as a plurality of layers, at least one of the layers may have an L-shape.

In some implementations, the first gate spacer 140 may serve as a guide for forming a self-aligned contact. Accordingly, the first gate spacer 140 may include a material having an etch selectivity to an interlayer insulating layer 190 according to an embodiment.

The first trench 140t may be defined by the first gate spacer 140. The first trench 140t may have, for example, the first gate spacer 140 as the sidewall of the trench and the upper surface of the substrate 100 as the bottom surface of the trench.

An interlayer insulating layer 190 may be formed on the substrate 100. The interlayer insulating layer 190 may surround the outer wall of the first gate spacer 140 defining the first trench 140t. The interlayer insulating layer 190 may include the first trench 140t defined by the first gate spacer 140.

The interlayer insulating layer 190 may include, but is not limited to, silicon oxide, silicon nitride, silicon oxynitride, flowable oxide (FOX), tonen silazen (TOSZ), undoped silica glass (USG), borosilicate glass (BSG), phosphosilicate glass (PSG), borophosphosilicate glass (BPSG), plasma enhanced tetra ethyl orthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric material or a combination thereof.

Although the interlayer insulating layer 190 is shown as a single layer, this is illustrative. The interlayer insulating layer 190 may include a plurality of layers to adjust the profile of the first trench 140t.

The first gate insulating layer 130 may be formed on the substrate 100. The first gate insulating layer 130 may be formed along the sidewalls and the bottom surface of the first trench 140t.

The first gate insulating layer 130 may include a first interfacial layer 131 and a first high-k insulating layer 132 sequentially stacked on the substrate 100 according to an embodiment.

The first interfacial layer 131 may be formed on the substrate 100. The first interfacial layer 131 may be formed on the bottom surface of the first trench 140t. Although the first interfacial layer 131 is shown as being not formed on the sidewalls of the first trench 140t, this is not limiting. The first interfacial layer 131 may be formed also on the sidewalls of the first trench 140t depending on the method of forming the first interfacial layer 131.

The first interfacial layer 131 may include, but is not limited to, silicon oxide. It is to be understood that the first interfacial layer 131 may include materials depending on the type of the substrate 100 or the type of the first high-k insulating layer 132.

The first high-k insulating layer 132 may be formed on the first interfacial layer 131. The first high-k insulating layer 132 may be formed along the bottom surface and sidewalls of the first trench 140t.

For example, the first high-k material may include at least one of: hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Although the oxides have been listed above as the material of the first high-k insulating layer 132, the first high-k insulating layer may comprise a nitride of the above-described metallic materials (hafnium nitride, for example) and/or an oxynitride of the above-described metallic materials (hafnium oxynitride, for example).

The first gate electrode structure 120 may be formed on the first gate insulating layer 130. The first gate electrode structure 120 may be used to fill the first trench 140t.

For example, the top surface of the first gate electrode structure 120 may be flush with the upper surface of the interlayer insulating layer 190 and the upper surface of the first gate spacer 140.

The first lower conductive layer 121 may be formed on the first gate insulating layer 130. The first lower conductive layer 121 may be in contact with the first gate insulating layer 130. For example, the first lower conductive layer 121 may be in contact with the first high-k insulating layer 132.

The first lower conductive layer 121 may extend along the side walls and the bottom surface of the first trench 140t. The first lower conductive layer 121 may be formed along the profile of the first gate insulating layer 130.

The first lower conductive layer 121 may include TiN, for example. In some embodiments, the first lower conductive layer 121 may be a TiN layer.

The first etch-stop conductive layer 122 may be formed on the first lower conductive layer 121. The first etch-stop conductive layer 122 may extend along the side walls and the bottom surface of the first trench 140t. The first etch-stop conductive layer 122 may be formed along the profile of the first lower conductive layer 121.

The first etch-stop conductive layer 122 may include, for example, TaN. In some embodiments, the first etch-stop conductive layer 122 may be a TaN layer.

The first lower conductive layer 121 and the first etch-stop conductive layer 122 are sequentially stacked on the first gate insulating layer 130.

The first n-type work function tuning layer 124 may be formed on the first etch-stop conductive layer 122. In the semiconductor device according to some embodiments of the present inventive concept, the first n-type work function tuning layer 124 may be in contact with the first etch-stop conductive layer 122.

The first n-type work function tuning layer 124 may extend along the side walls and the bottom surface of the first trench 140t. The first n-type work function tuning layer 124 may be formed along the profile of the first etch-stop conductive layer 122.

The first n-type work function tuning layer 124 may include one of TiAl, TiAIN, TiAlC and TiAlCN, for example. In addition, the first n-type work function tuning layer 124 may include the above-described materials in which Ti has been substituted with one of Ta, W, Ru, Nb, Mo, Hf and La.

In the semiconductor device according to some embodiments of the present inventive concept, the first n-type work function tuning layer 124 is described as a layer comprising TiAlC.

The first barrier conductive layer 125 may include a first lower barrier conductive layer 126 and a first upper barrier conductive layer 127 sequentially stacked on the first n-type work function tuning layer 124 according to an embodiment.

The first barrier conductive layer 125 may be in contact with the first n-type work function tuning layer 124. In an embodiment, there may be no layer interposed between the first barrier conductive layer 125 and the first n-type work function tuning layer 124.

The first lower barrier conductive layer 126 may extend along the side walls and the bottom surface of the first trench 140t. The first lower barrier conductive layer 126 may be formed along the profile of the first n-type work function tuning layer 124. The first lower barrier conductive layer 126 may be in contact with the first n-type work function tuning layer 124.

The first upper barrier conductive layer 127 may extend along the side walls and the bottom surface of the first trench 140t. The first upper barrier conductive layer 127 may be formed along the profile of the first lower barrier conductive layer 126. The first upper barrier conductive layer 127 may be in contact with the first lower barrier conductive layer 126.

The first lower barrier conductive layer 126 and the first upper barrier conductive layer 127 may comprise the same material, for example. The first lower barrier conductive layer 126 and the first upper barrier conductive layer 127 may each include, for example, TiN. In some embodiments, the first lower barrier conductive layer 126 and the first upper barrier conductive layer 127 may each be a TiN layer.

The first lower barrier conductive layer 126 and the first upper barrier conductive layer 127 comprise the same material. However, an interface may be formed between the first lower barrier conductive layer 126 and the first upper barrier conductive layer 127.

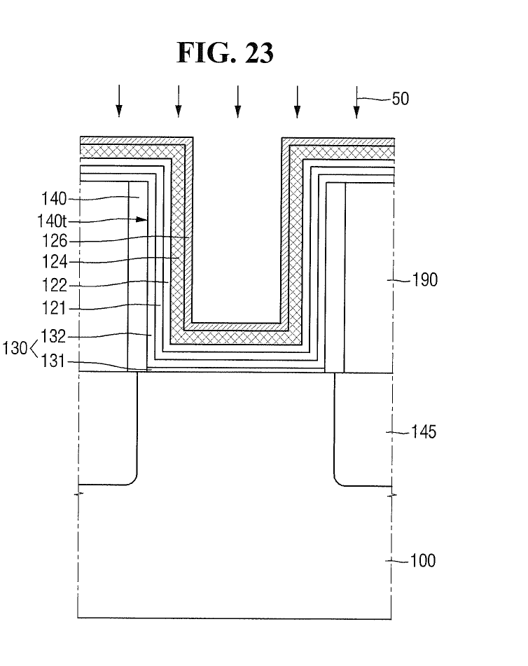

The boundary between the first lower barrier conductive layer 126 and the first upper barrier conductive layer 127 may be formed via a film treatment process 50 (see e.g., FIG. 23) performed after the first lower barrier conductive layer 126 has been formed.

The first lower barrier conductive layer 126 may have a thickness so that it can prevent the first n-type work function tuning layer 124 from being re-oxidized after the film treatment process 50 (see e.g., FIG. 23).

Each of the first lower barrier conductive layer 126 and the first upper barrier conductive layer 127 may have a thickness of 10 Å or more. In an embodiment, each of the first lower barrier conductive layer 126 and the first upper barrier conductive layer 127 may have a thickness of at least two layers of TiN lattice, for example.

In some embodiments, the thickness of the first upper barrier conductive layer 127 may be equal to or greater than the thickness of the first lower barrier conductive layer 126, for example.

The first filling conductive layer 128 may be formed on the first barrier conductive layer 125. A first filling conductive layer 128 may be formed on the first upper barrier conductive layer 127. The first filling conductive layer 128 may be used to fill the space of the first trench 140t that remains after the first lower conductive layer 121, the first etch-stop conductive layer 122, the first n-type work function tuning layer 124 and the first barrier conductive layer 125 have been formed.

The first filling conductive layer 128 may include, for example, at least one of W, Al, Co, Cu, Ru, Ni, Pt, and Ni—Pt.

The first source/drain region 145 may be fainted adjacent to the first gate electrode structure 120.

Although the first source/drain region 145 is shown as an impurity region formed in the substrate 100, this is illustrative. The first source/drain region 145 may comprise an epitaxial layer formed on or in the substrate 100.

In an embodiment, the first source/drain region 145 may be an elevated source/drain region including an upper surface protruding from the upper surface of the substrate 100.

The conductivity type of the impurity comprised in the first source/drain region 145 varies depending on whether the semiconductor device including the first gate electrode structure 120 is a PMOS or NMOS device.

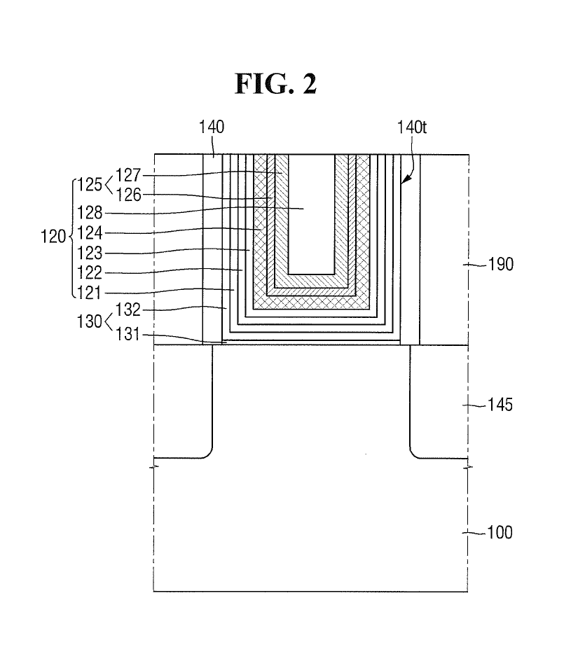

FIG. 2 is a diagram for illustrating a semiconductor device according to some exemplary embodiments of the present inventive concept.

Referring to FIG. 2, in the semiconductor device according to some embodiments of the present inventive concept, the first gate electrode structure 120 may further include a first p-type work function tuning layer 123.

The first p-type work function tuning layer 123 may be formed between the first gate insulating layer 130 and the first n-type work function tuning layer 124. For example, the first p-type work function tuning layer 123 may be formed between the first etch-stop conductive layer 122 and the first n-type work function tuning layer 124.

The first p-type work function tuning layer 123 may extend along the side walls and the bottom surface of the first trench 140t. The first p-type work function tuning layer 123 may be formed along the profile of the first etch-stop conductive layer 122.

The first p-type work function tuning layer 123 may include, for example, TiN.

In FIG. 2, the first p-type work function tuning layer 123 is shown as extending to the top surface of the first gate electrode structure 120, but this is not limiting.

In an embodiment, the first p-type work function tuning layer 123 may be chamfered. The upper surface of the first p-type work function tuning layer 123 may include an inclined surface making an acute angle with respect to the side walls of the first trench 140t.

In an embodiment, the uppermost surface of the first p-type work function tuning layer 123 may be lower than the top surface of the first gate electrode structure 120, with respect to the upper surface of the interlayer insulating layer 190. The uppermost surface of the first p-type work function tuning layer 123 may be covered with the first n-type work function tuning layer 124.

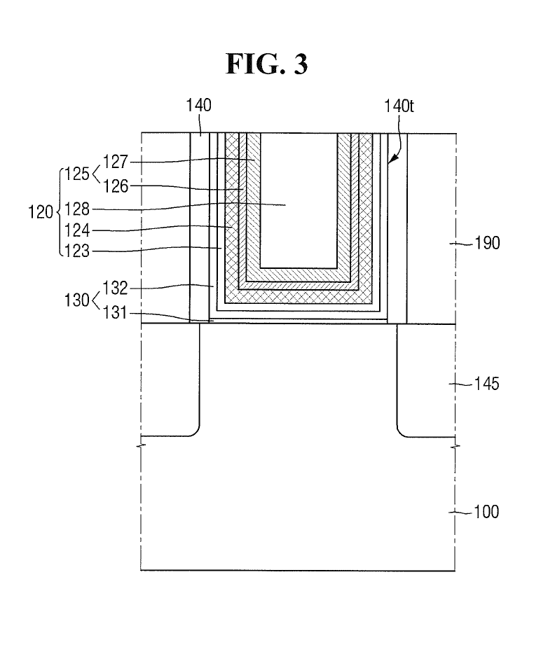

FIG. 3 is a diagram for illustrating a semiconductor device according to some exemplary embodiments of the present inventive concept. Referring to FIG. 3, in the semiconductor device according to some embodiments of the present inventive concept, the first p-type work function tuning layer 123 may be in contact with the first gate insulating layer 130. The first p-type work function tuning layer 123 may be in contact with the first high-k insulating layer 132.

According to an embodiment, the first lower conductive layer 121 and a first etch-stop conductive layer 122 may not be interposed between the first p-type work function tuning layer 123 and the first gate insulating layer 130.

The first p-type work function tuning layer 123 may be formed between the first gate insulating layer 130 and the first n-type work function tuning layer 124. The first p-type work function tuning layer 123 may be formed along the profile of the first gate insulating layer 130.

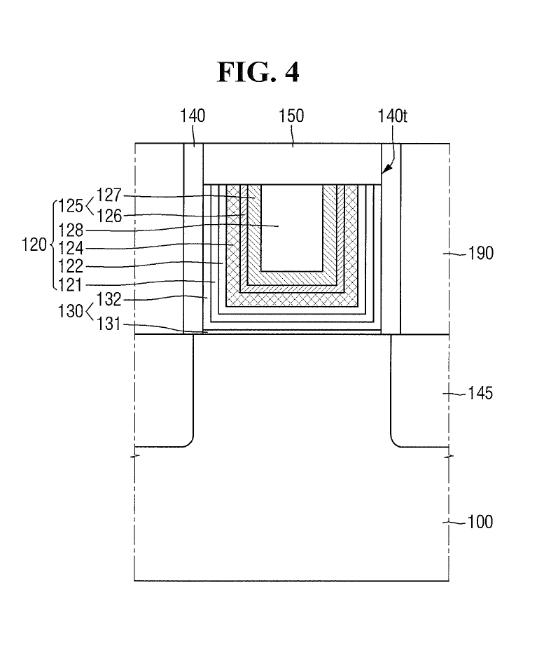

FIG. 4 is a diagram for illustrating a semiconductor device according to some exemplary embodiments of the present inventive concept. Referring to FIG. 4, the semiconductor device according to some embodiments of the present inventive concept may further include a capping pattern 150.

The first gate electrode structure 120 may be used to fill a portion of the first trench 140t. For example, the top surface of the first gate electrode structure 120 may be closer to the substrate 100 than the upper surface of the interlayer insulating layer 190.

The capping pattern 150 may be formed on the first gate electrode structure 120 and the first gate insulating layer 130. In an embodiment, the capping pattern 150 may be formed on the first lower conductive layer 121, the first etch-stop conductive layer 122, the first n-type work function tuning layer 124, the first barrier conductive layer 125 and the first filling conductive layer 128.

The capping pattern 150 may be formed by filling a portion of the first trench 140t. As the capping pattern 150 is formed by filling the portion of the first trench 140t, the top surface of the capping pattern 150 may be flush with the top surface of the first gate spacer 140 and the top surface of the interlayer insulating layer 190.

The capping pattern 150 may serve as a guide for forming a self-aligned contact, and thus may include a material having an etch selectivity to the interlayer insulating layer 190. The capping pattern 150 may include at least one of silicon nitride (SiN), silicon oxynitride (SiON), silicon oxide (SiO₂), silicon carbonitride (SiCN), silicon oxycarbonitride (SiOCN) and the combination thereof.

According to an embodiment, the first gate insulating layer 130 may extend between the first gate spacer 140 and the capping pattern 150. That is, a part of the first gate insulating layer 130 may extend between the inner wall of the first gate spacer 140 and the side wall of the capping pattern 150.

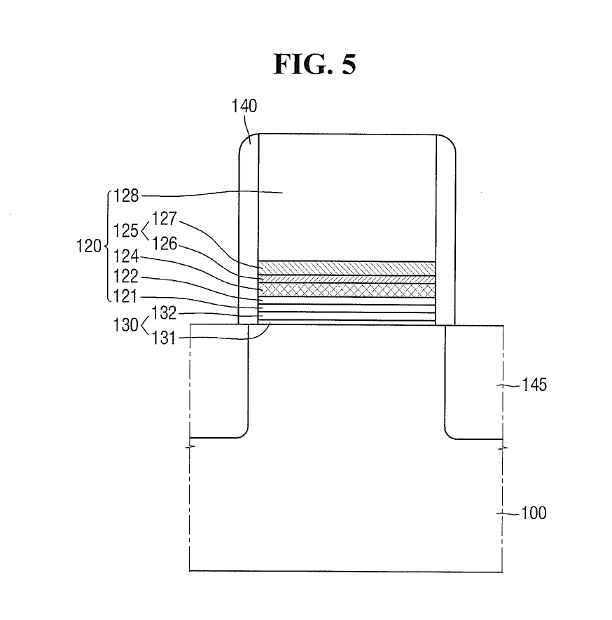

FIG. 5 is a diagram for illustrating a semiconductor device according to some exemplary embodiments of the present inventive concept. Referring to FIG. 5, in the semiconductor device according to some embodiments of the present inventive concept, the first high-k insulating layer 132 may not include a portion extending between the first gate electrode structure 120 and the first gate spacer 140.

In addition, in the first gate electrode structure 120, the first lower conductive layer 121, the first etch-stop conductive layer 122, the first n-type work function tuning layer 124, the first barrier conductive layer 125 may not include the portions extending along the inner wall of the first gate spacer 140.

In an embodiment, a gate hard mask may be further formed on the first filling conductive layer 128.

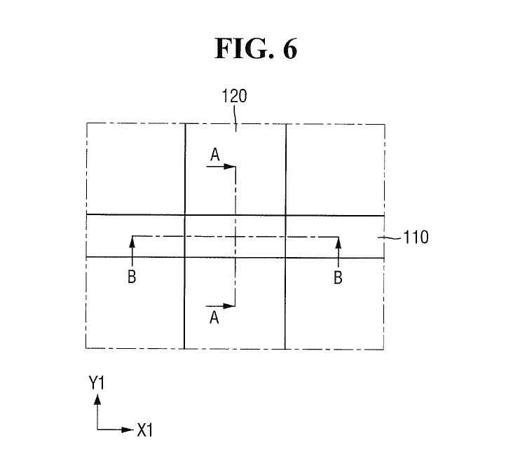

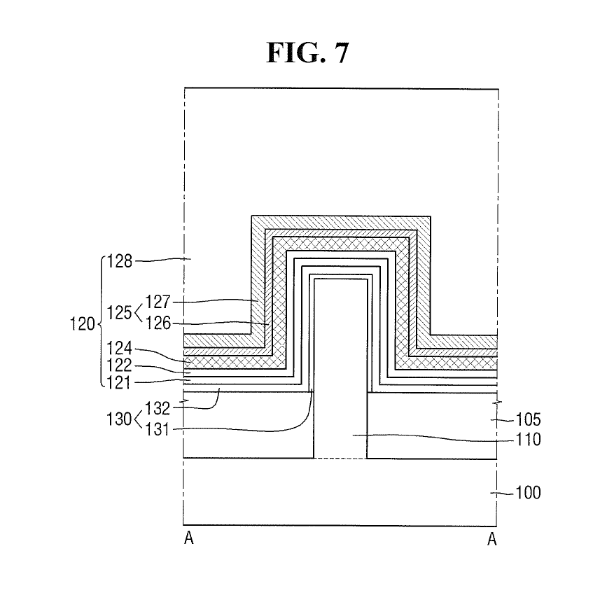

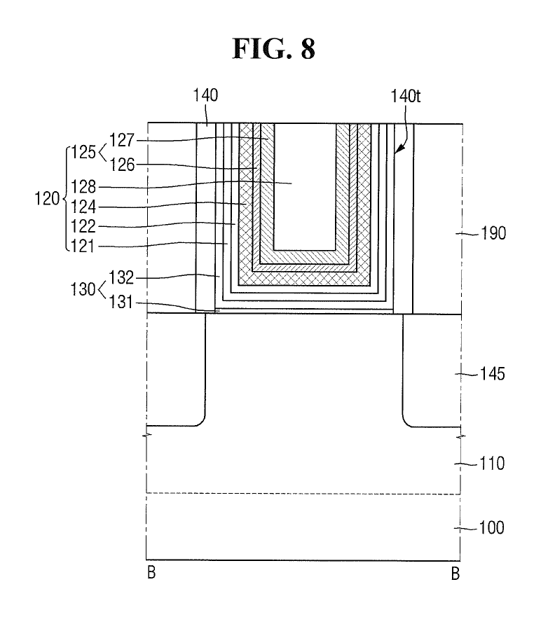

FIG. 6 is a layout diagram for illustrating a semiconductor device according to some exemplary embodiments of the present inventive concept. FIG. 7 is a cross-sectional view taken along line A-A of FIG. 6. FIG. 8 is a cross-sectional view taken along line B-B of FIG. 6.

Referring to FIGS. 6 to 8, the semiconductor device according to some exemplary embodiments of the present inventive concept may include a first multi-channel active region 110, a first gate electrode structure 120, a first gate spacer 140, and a first gate insulating layer 130.

For example, the first multi-channel active region 110 may be a fin-shaped pattern. In an embodiment, the first multi-channel active region 110 may be a nanosheet or a nanowire.

In the following description, it is assumed that the first multi-channel active region 110 is a fin-shaped pattern.

The first multi-channel active region 110 may protrude from the substrate 100. The first multi-channel active region 110 may extend on the substrate 100 along a first direction X1. For example, the first multi-channel active region 110 may include a longer side extending in the first direction X1 and a shorter side extending in a second direction Y1.

The first multi-channel active region 110 may be a part of the substrate 100 or may include an epitaxial layer grown from the substrate 100. The first multi-channel active region 110 may comprise, for example, silicon or germanium, which is an elemental semiconductor material. In an embodiment, the first multi-channel active region 110 may comprise a compound semiconductor, for example, a group IV-IV compound semiconductor or a group III-V compound semiconductor.

As examples of the group IV-IV compound semiconductor, the first multi-channel active region 110 may be a binary compound or a ternary compound including at least two of carbon (C), silicon (Si), germanium (Ge) and tin (Sn), or such a compound doped with an group IV element. As examples of group III-V compound semiconductor, the first multi-channel active region 110 may be binary compound, ternary compound or quaternary compound formed by bonding at least one of aluminum (Al), gallium (Ga) and indium (In) as group III element with one of phosphorous (P), arsenic (As) and antimony (Sb) as group V element.

In a semiconductor device according to some embodiments of the present inventive concept, the first multi-channel active region 110 is described as a silicon fin-shaped pattern comprising silicon.

A field insulating layer 105 may be formed on the substrate 100. The field insulating layer 105 may cover a part of the first multi-channel active region 110. For example, the field insulating layer 105 may cover a part of the side walls of the first multi-channel active region 110.

The upper surface of the first multi-channel active region 110 may protrude from the upper surface of the field insulating layer 105 formed adjacent to the longer side of the first multi-channel active region 110. The first multi-channel active region 110 may be defined by the field insulating layer 105 on the substrate 100.

The field insulating layer 105 may include, but is not limited to, silicon oxide, silicon nitride, silicon oxynitride, flowable oxide (FOX), tonen silazen (TOSZ), undoped silica glass (USG), borosilicate glass (B SG), phosphosilicate glass (PSG), borophosphosilicate glass (BPSG), plasma enhanced tetra ethyl orthosilicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SILK, polyimide, porous polymeric material or a combination thereof.

In addition, the field insulating layer 105 may further include at least one field liner formed between the first multi-channel active region 110 and the field insulating layer 105. When the field insulating layer 105 further includes the field liner, the field liner may include at least one of polysilicon, amorphous silicon, silicon oxynitride, silicon nitride, and silicon oxide.

The first gate spacer 140 may be formed on the first multi-channel active region 110 protruding from the field insulating layer 105. The first gate spacer 140 may extend long along the second direction Y1 and may intersect the first multi-channel active region 110. The first trench 140t is defined by the first gate spacer 140, and thus the first trench 140t is elongated along the second direction Y1 so as to intersect the first multi-channel active region 110.

The first gate insulating layer 130 may be formed on the field insulating layer 105 and the first multi-channel active region 110. The first gate insulating layer 130 may be formed on the top surface of the field insulating layer 105 and along the profile of the first multi-channel active region 110.

The first interfacial layer 131 may be formed on the first multi-channel active region 110. The first interfacial layer 131 may be formed along the profile of the first multi-channel active region 110 protruding from the top surface of the field insulating layer 105. Although the first interfacial layer 131 is shown as being not formed on the upper surface of the field insulating layer 105, it is not limiting. The first interfacial layer 131 may be formed along the upper surface of the field insulating layer 105 depending on the method of forming the first interfacial layer 131.

The first high-k insulating layer 132 may be formed on the first interfacial layer 131 and along the profile of the first multi-channel active region 110 and the upper surface of the field insulating layer 105.

The first gate electrode structure 120 is formed on the first gate insulating layer 130 and may intersect the first multi-channel active region 110. That is, each of the first lower conductive layer 121, the first etch-stop conductive layer 122, the first n-type work function tuning layer 124, the first barrier conductive layer 125, and the first filling conductive layer 128 may intersect the first multi-channel active region 110.

Each of the first lower conductive layer 121, the first etch-stop conductive layer 122, the first n-type work function tuning layer 124 and the first barrier conductive layer 125 may include a portion formed along the profile of the first multi-channel active region 110 protruding from the upper surface of the field insulating layer 105 and a portion extending along the upper surface of the field insulating layer 105.

The first source/drain region 145 may be formed in the first multi-channel active region 110. The first source/drain region 145 may comprise an epitaxial layer formed in the first multi-channel active region 110 or on the first multi-channel active region 110.

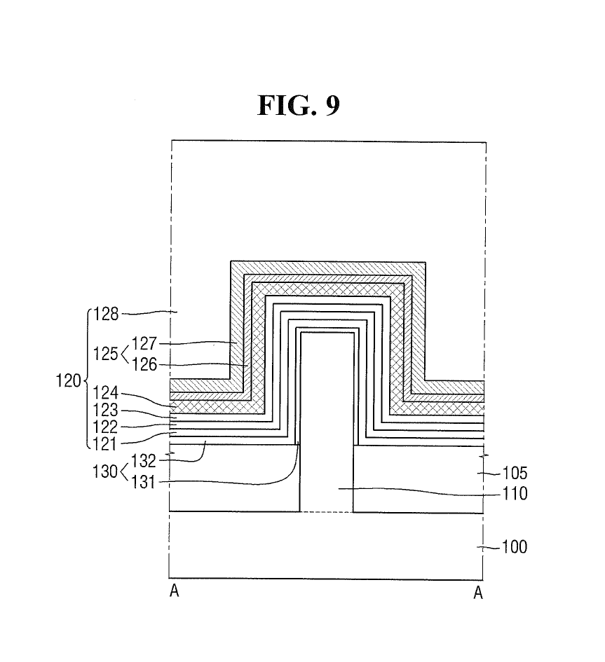

FIG. 9 is a diagram for illustrating a semiconductor device according to some exemplary embodiments of the present inventive concept.

Referring to FIG. 9, in the semiconductor device according to some embodiments of the present inventive concept, the first gate electrode structure 120 may further include a first p-type work function tuning layer 123.

The first p-type work function tuning layer 123 may be formed between the first gate insulating layer 130 and the first n-type work function tuning layer 124. For example, the first p-type work function tuning layer 123 may be formed between the first etch-stop conductive layer 122 and the first n-type work function tuning layer 124.

The first p-type work function tuning layer 123 may be formed along the profile of the first etch-stop conductive layer 122. The first p-type work function tuning layer 123 may include a portion formed along the profile of the first multi-channel active region 110 protruding from the upper surface of the field insulating layer 105, and a portion formed along the upper surface of the field insulating layer 105.

In some embodiments, the capping pattern 150 of FIG. 4 may be further formed on the first gate electrode structure 120.

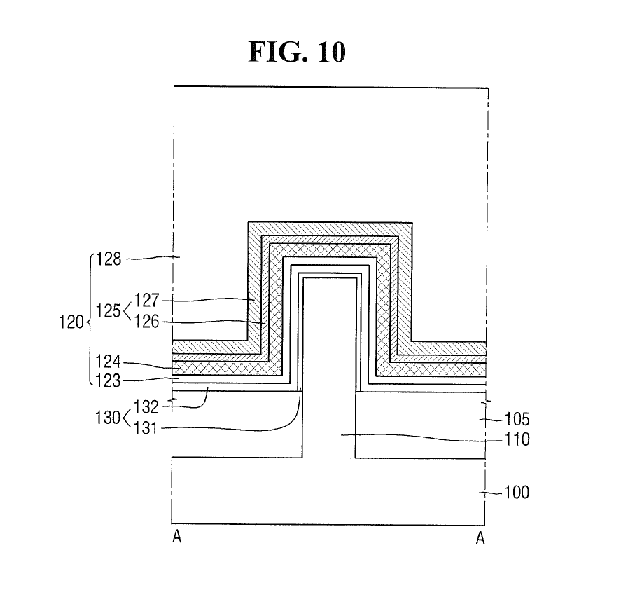

FIG. 10 is a diagram for illustrating a semiconductor device according to some exemplary embodiments of the present inventive concept. Referring to FIG. 10, in the semiconductor device according to some embodiments of the present inventive concept, the first p-type work function tuning layer 123 may be in contact with the first gate insulating layer 130.

The first lower conductive layer 121 and the first etch-stop conductive layer 122 may not be interposed between the first p-type work function tuning layer 123 and the first gate insulating layer 130.

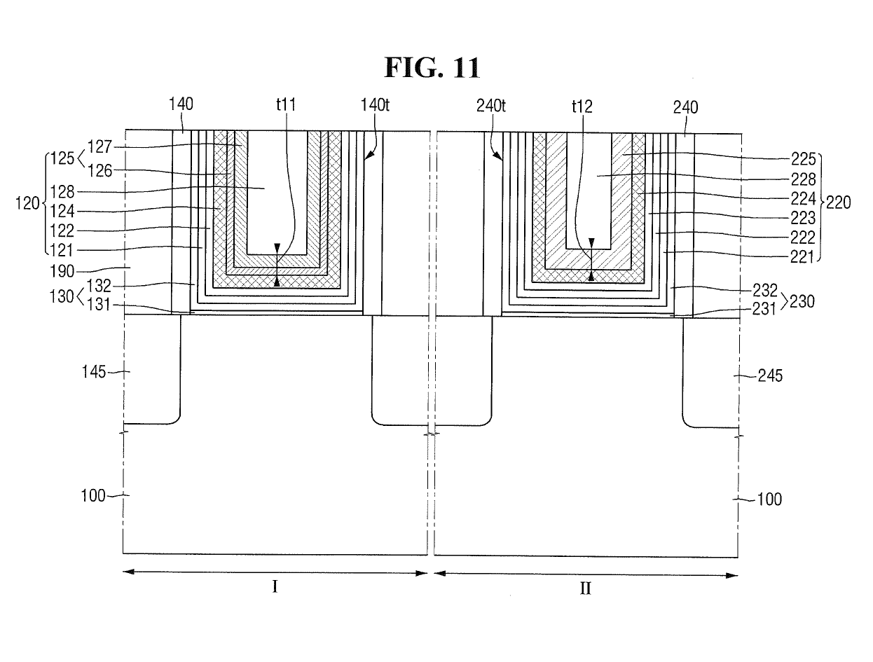

FIG. 11 is a diagram for illustrating a semiconductor device according to some exemplary embodiments of the present inventive concept. A first area I shown in FIG. 11 is substantially identical to what is shown in FIG. 1.

Referring to FIG. 11, the semiconductor device according to some exemplary embodiments of the present inventive concept may include a substrate 100 including a first area I and a second area II, a first gate electrode structure 120 formed in the first area I, and a second gate electrode structure 220 formed in the second area II.

The substrate 100 may include the first area I and the second area II. The first area I and the second area II may be spaced apart from each other or may be connected to each other.

In the semiconductor device according to some embodiments of the present inventive concept, transistors of different types may be formed in the first area I and the second area II, respectively. For example, NMOS transistors and PMOS transistors may be formed in the first area I and the second area II, respectively.

The second gate electrode structure 220 may include a second lower conductive layer 221, a second etch-stop conductive layer 222, a second p-type work function tuning layer 223, a second n-type work function tuning layer 224, a second barrier conductive layer 225, and a second filling conductive layer 228.

A second gate spacer 240 may be formed on the substrate 100 in the second area II. Although the second gate spacer 240 is shown as a single layer, this is illustrative. For example, the second gate spacer 240 may be formed as multiple layers.

A second trench 240t may be defined by the second gate spacer 240. The second trench 240t may have, for example, the second gate spacer 240 as the sidewall of the trench and the upper surface of the substrate 100 as the bottom surface of the trench.

The interlayer insulating layer 190 may surround the outer walls of the second gate spacer 240 defining the second trench 240t. The interlayer insulating layer 190 may include the first trench 140t defined by the first gate spacer 140 and the second trench 240t defined by the second gate spacer 240.

The second gate insulating layer 230 may be formed on the substrate 100. The second gate insulating layer 230 may be formed along the sidewalls and the bottom surface of the second trench 240t.

The second gate insulating layer 230 may include a second interfacial layer 231 and a second high-k insulating layer 232 sequentially stacked on the substrate 100.

The second interfacial layer 231 may be formed on the substrate 100. The second interfacial layer 231 may be formed on the bottom surface of the second trench 240t. Although the second interfacial layer 231 is shown as being not formed on the sidewalls of the second trench 240t, it is not limiting. The second interfacial layer 231 may include, but is not limited to, silicon oxide.

The second high-k insulating layer 232 may be formed on the second interfacial layer 231. The second high-k insulating layer 232 may be formed along the bottom surface andsidewalls of the second trench 240t.

The second gate electrode structure 220 may be formed on the second gate insulating layer 230. The second gate electrode structure 220 may be used to fill the second trench 240t. For example, the top surface of the second gate electrode structure 220 may be flush with the upper surface of the interlayer insulating layer 190 and the upper surface of the second gate spacer 240.

The second lower conductive layer 221 may be formed on the second gate insulating layer 230. The second lower conductive layer 221 may be in contact with the second gate insulating layer 230. For example, the second lower conductive layer 221 may be in contact with the second high-k insulating layer 232.

The second lower conductive layer 221 may extend along the side walls and the bottom surface of the second trench 240t. The second lower conductive layer 221 may be formed along the profile of the second gate insulating layer 230.

The second lower conductive layer 221 may include TiN, for example. In some embodiments, the second lower conductive layer 221 may be a TiN layer.

The second etch-stop conductive layer 222 may be formed on the second lower conductive layer 221. The second etch-stop conductive layer 222 may extend along the side walls and the bottom surface of the second trench 240t. The second etch-stop conductive layer 222 may be formed along the profile of the second lower conductive layer 221.

The second etch-stop conductive layer 222 may include, for example, TaN. In some embodiments, the second etch-stop conductive layer 222 may be a TaN layer.

The second lower conductive layer 221 and the second etch-stop conductive layer 222 are sequentially stacked on the second gate insulating layer 230.

The second p-type work function tuning layer 223 may be formed on the second etch-stop conductive layer 222. The second p-type work function tuning layer 223 may extend along the side walls and the bottom surface of the second trench 240t. The second p-type work function tuning layer 223 may be formed along the profile of the second etch-stop conductive layer 222.

The second p-type work function tuning layer 223 may include, for example, TiN.

The second n-type work function tuning layer 224 may be formed on the second p-type work function tuning layer 223. The second n-type work function tuning layer 224 may extend along the side walls and the bottom surface of the second trench 240t. The second n-type work function tuning layer 224 may be formed along the profile of the second p-type work function tuning layer 223.

For example, the second n-type work function tuning layer 224 may comprise the same material as the first n-type work function tuning layer 124. In the semiconductor device according to some embodiments of the present inventive concept, each of the first n-type work function tuning layer 124 and the second n-type work function tuning layer 224 comprises TiAlC.

In FIG. 11, the second p-type work function tuning layer 223 is shown as extending to the top surface of the second gate electrode structure 220, but this is illustrative.

In an embodiment, the second p-type work function tuning layer 223 may be chamfered. The uppermost surface of the second p-type work function tuning layer 223 may include an inclined surface making an acute angle with respect to the side walls of the second trench 240t. In an embodiment, the uppermost surface of the second p-type work function tuning layer 223 may be lower than the top surface of the second gate electrode structure 220, with respect to the upper surface of the interlayer insulating layer 190. The uppermost surface of the second p-type work function tuning layer 223 may be covered with the second n-type work function tuning layer 224.

The second barrier conductive layer 225 may be formed on the second n-type work function tuning layer 224. For example, the second barrier conductive layer 225 may be in contact with the second n-type work function tuning layer 224.

The second barrier conductive layer 225 may extend along the side walls and the bottom surface of the second trench 240t. The second barrier conductive layer 225 may be formed along the profile of the second n-type work function tuning layer 224.

The second barrier conductive layer 225 may include the first lower barrier conductive layer 126 and the first upper barrier conductive layer 127. The second barrier conductive layer 225 may include TiN, for example. In some embodiments, the second barrier conductive layer 225, the first barrier conductive layer 126 and the first upper barrier conductive layer 127 may each be a TiN layer.

In the semiconductor device according to some embodiments of the present inventive concept, the thickness t12 of the second barrier conductive layer 225 is greater than the thickness of the first lower barrier conductive layer 126 and the thickness of the first upper barrier conductive layer 127.

In an embodiment, the thickness t12 of the second barrier conductive layer 225 may be substantially equal to the thickness tll of the first barrier conductive layer 125. The thickness t12 of the second barrier conductive layer 225 may be substantially equal to the sum of the thickness of the first lower barrier conductive layer 126 and the thickness of the first upper barrier conductive layer 127.

The second filling conductive layer 228 may be formed on the second barrier conductive layer 225. The second filling conductive layer 228 may be used to fill the space of the second trench 240t that remains after the second lower conductive layer 221, the second etch-stop conductive layer 222, the second p-type work function tuning layer 223, the second n-type work function tuning layer 224, and the second barrier conductive layer 225 have been formed.

The second filling conductive layer 228 may comprise the same material as the first filling conductive layer 128.

The second source/drain region 245 may be formed adjacent to the first gate electrode structure 120. Although the second source/drain region 245 is shown as an impurity region formed in the substrate 100, this is illustrative. The second source/drain region 245 may comprise an epitaxial layer formed on or in the substrate 100.

In an embodiment, the second source/drain region 245 may be an elevated source/drain region including an upper surface protruding from the upper surface of the substrate 100.

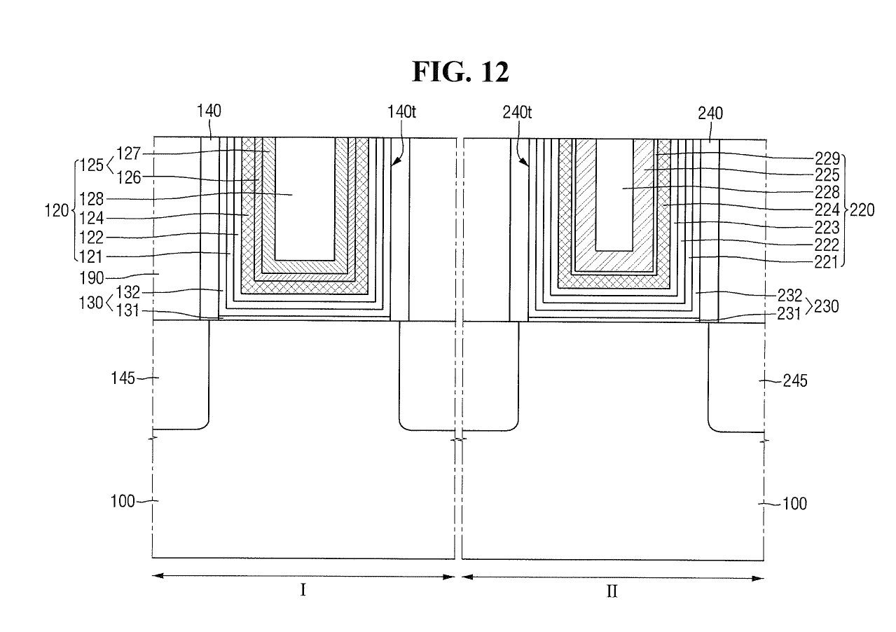

FIG. 12 is a diagram for illustrating a semiconductor device according to some exemplary embodiments of the present inventive concept. Referring to FIG. 12, in the semiconductor device according to some embodiments of the present inventive concept, the second gate electrode structure 220 may further include an inserted insulating layer 129.

The inserted insulating layer 129 may be formed between the second n-type work function tuning layer 224 and the second barrier conductive layer 225. The inserted insulating layer 129 may be in contact with the second n-type work function tuning layer 224 and the second barrier conductive layer 225.

The inserted insulating layer 229120 may extend along the side walls and the bottom surface of the second trench 240t. The inserted insulating layer 129 may be formed along the profile of the second n-type work function tuning layer 224.

For example, the inserted insulating layer 129 may include oxide of the second n-type work function tuning layer 224.

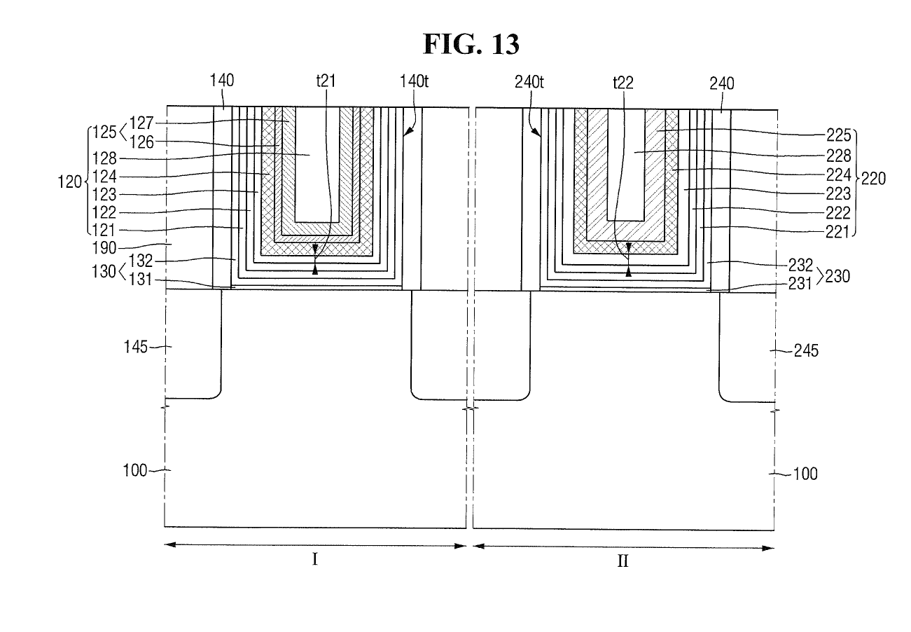

FIG. 13 is a diagram for illustrating a semiconductor device according to some exemplary embodiments of the present inventive concept. Referring to FIG. 13, in the semiconductor device according to some embodiments of the present inventive concept, the first gate electrode structure 120 may further include a first p-type work function tuning layer 123.

The first p-type work function tuning layer 123 may be formed between the first etch-stop conductive layer 122 and the first n-type work function tuning layer 124. The first p-type work function tuning layer 123 may extend along the side walls and the bottom surface of the first trench 140t. The first p-type work function tuning layer 123 may be formed along the profile of the first etch-stop conductive layer 122.

The first p-type work function tuning layer 123 and the second p-type work function tuning layer 223 may include, for example, TiN.

In the semiconductor device according to some exemplary embodiments of the present inventive concept, the thickness t22 of the second p-type work function tuning layer 223 may be larger than the thickness t21 of the first p-type work function tuning layer 123.

In an embodiment, the inserted insulating layer 129 (see e.g., FIG. 12) may be formed between the second n-type work function tuning layer 224 and the second barrier conductive layer 225.

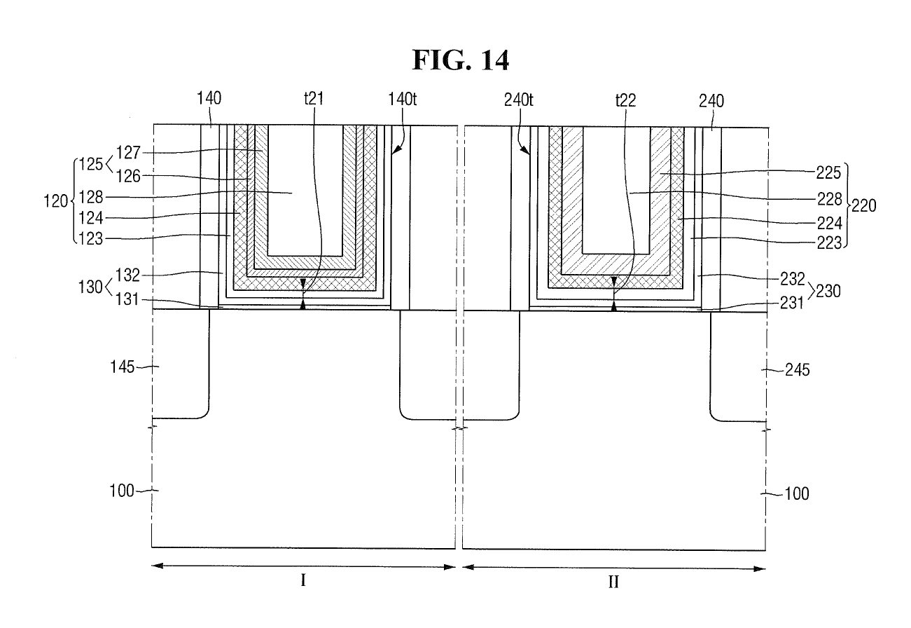

FIG. 14 is a diagram for illustrating a semiconductor device according to some exemplary embodiments of the present inventive concept.

Referring to FIG. 14, in the semiconductor device according to some embodiments of the present inventive concept, the first p-type work function tuning layer 123 may be in contact with the first gate insulating layer 130. The second p-type work function tuning layer 223 may be in contact with the second gate insulating layer 230.

The first lower conductive layer 121 and the first etch-stop conductive layer 122 may not be interposed between the first p-type work function tuning layer 123 and the first gate insulating layer 130. The second lower conductive layer 221 and the second etch-stop conductive layer 222 may not be interposed between the second p-type work function tuning layer 223 and the second gate insulating layer 230.

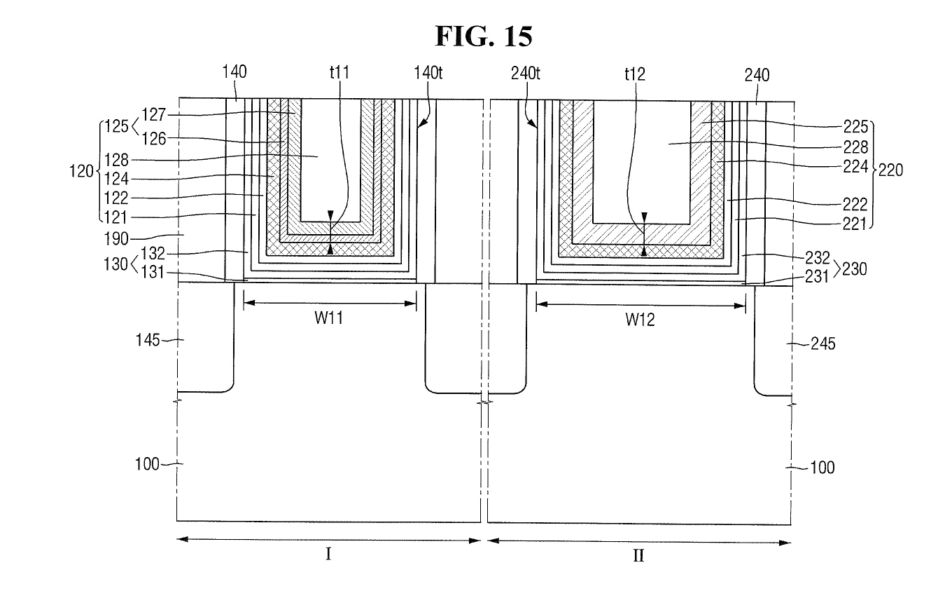

FIG. 15 is a diagram for illustrating a semiconductor device according to some exemplary embodiments of the present inventive concept. Referring to FIG. 15, in the semiconductor device according to some embodiments of the present inventive concept, the width W11 of the first trench 140t is smaller than the width W12 of the second trench 240t.

For example, the width W11 of the first source/drain region 145 between the first gate spacers 140 is smaller than the width W12 of the second source/drain region 245 between the second gate spacers 240.

In the semiconductor device according to some embodiments of the present inventive concept, transistors of the same type may be formed in the first area I and the second area II, respectively. For example, NMOS or PMOS transistors may be formed in the first area I and the second area II.

In the second gate electrode structure 220, the second p-type work function tuning layer 223 may not be interposed between the second n-type work function tuning layer 224 and the second etch-stop conductive layer 222. The second etch-stop conductive layer 222 may be in contact with the second n-type work function tuning layer 224.

In an embodiment, the inserted insulating layer 129 (see e.g., FIG. 12) comprising oxide of the second n-type work function tuning layer may be formed between the second n-type work function tuning layer 224 and the second barrier conductive layer 225.

The structure of the conductive layer stacked between the first gate insulating layer 130 and the first barrier conductive layer 125 may be identical to the structure of the conductive layer stacked between the second gate insulating layer 230 and the second barrier conductive layer 225, except for the inserted insulating layer comprising the oxide of the second n-type work function tuning layer.

Although FIG. 15 depicts the structure of the stacked conductive layers of the first gate electrode structure 120 and the structure of the stacked conductive layers of the second gate electrode structure 220 are similar to the structure of the first gate electrode structure 120 of FIG. 1, this is not limiting.

That is, it is to be understood that the structure of the stacked conductive layers of the first gate electrode structure 120 and the structure of the stacked conductive layers of the second gate electrode structure 220 may be similar to the structure of the first gate electrode structure 120 of FIG. 2 or 3.

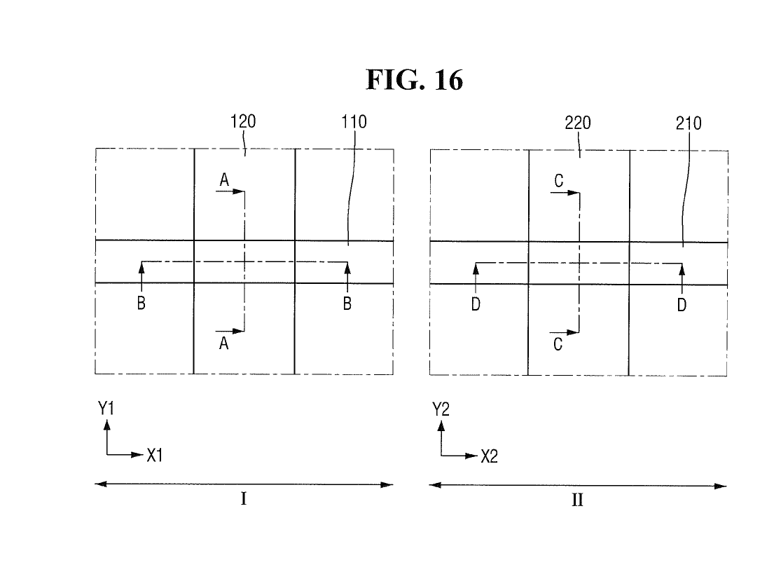

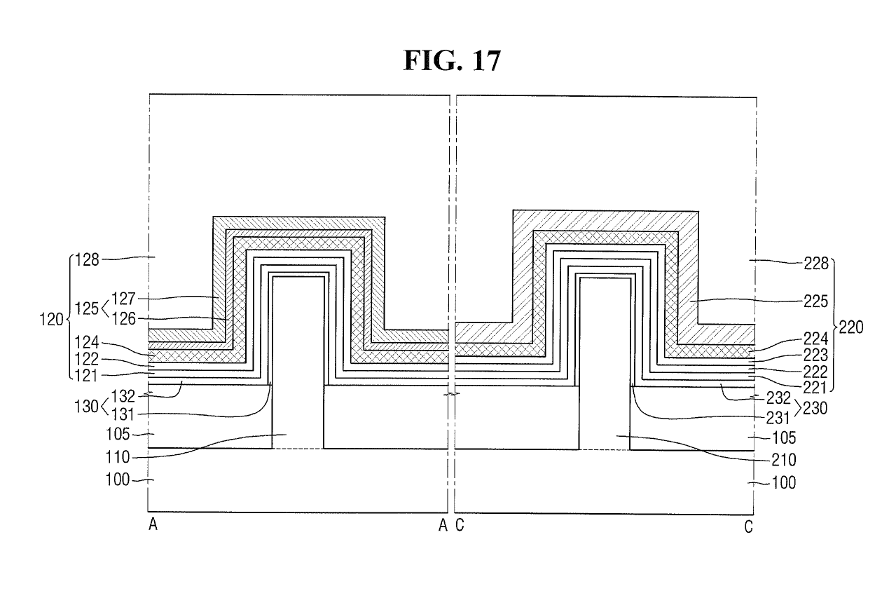

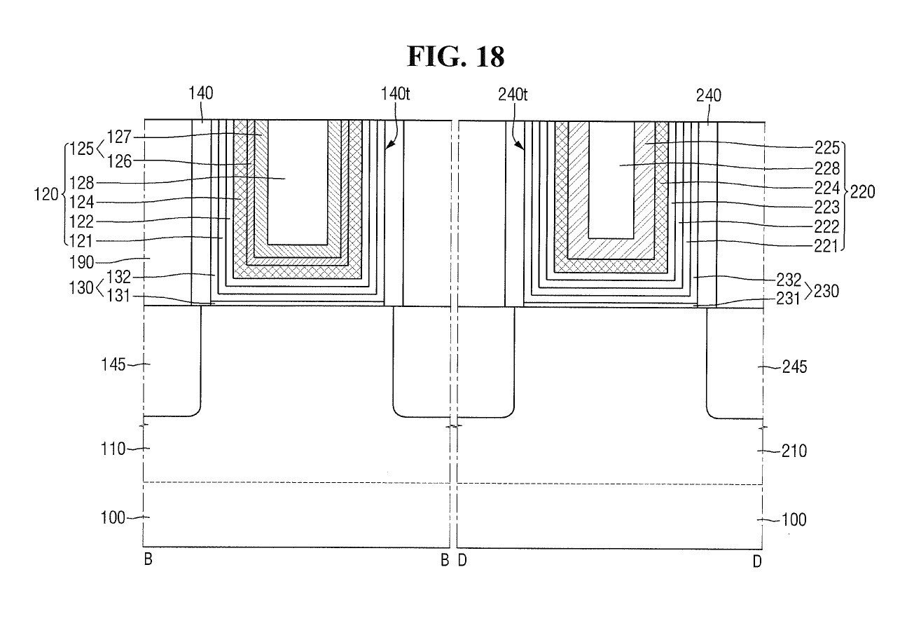

FIG. 16 is a layout diagram for illustrating a semiconductor device according to some exemplary embodiments of the present inventive concept. FIG. 17 is a cross-sectional view taken along line A-A and line C-C of FIG. 16. FIG. 18 is a cross-sectional view taken along line B-B and line D-D of FIG. 16. The first area I shown in FIGS. 16 to 18 is substantially identical to the first area I shown in FIGS. 6 to 8.

Referring to FIGS. 16 to 18, a semiconductor device according to some embodiments of the present inventive concept includes a first multi-channel active region 110, a second multi-channel active region 210, a first gate electrode structure 120, a second gate electrode structure 220, a first gate spacer 140, a second gate spacer 240, a first gate insulating layer 130, and a second gate insulating layer 230.

For example, the first multi-channel active region 110 and the second multi-channel active region 210 may be a fin-shaped pattern. In an embodiment, the first multi-channel active region 110 and the second multi-channel active region 210 may be nanosheets or nanowires. However, the above-described materials are merely examples of the first multi-channel active region 110, but they are not limiting.

In the following description, it is assumed that the first multi-channel active region 110 and the second multi-channel active region 210 are fin-shaped patterns.

The first multi-channel active region 110, the first gate electrode structure 120, the first gate spacer 140, and the first gate insulating layer 130 may be disposed on the substrate 100 in the first area I.

The second multi-channel active region 210 may protrude from the substrate 100. The second multi-channel active region 210 may extend on the substrate 100 along a third direction X2. For example, the second multi-channel active region 210 may include a longer side extending in the third direction X2 and a shorter side extending in a fourth direction Y2.

The second multi-channel active region 210 may be a part of the substrate 100 or may include an epitaxial layer grown from the substrate 100. The second multi-channel active region 210 may comprise, for example, silicon or germanium, which is an elemental semiconductor material. In an embodiment, the second multi-channel active region 210 may comprise a compound semiconductor, for example, a group IV-IV compound semiconductor or a group III-V compound semiconductor.

A field insulating layer 105 may be formed on the substrate 100. The field insulating layer 105 may cover a part of the second multi-channel active region 210. For example, the field insulating layer 105 may cover a part of the side walls of the second multi-channel active region 210.

The second gate spacer 240 may be formed on the second multi-channel active region 210 protruding from the field insulating layer 105. The second gate spacer 240 may extend long along the fourth direction Y2 and may intersect the second multi-channel active region 210. The second trench 240t is defined by the second gate spacer 240, and thus the second trench 240t is elongated along the fourth direction Y2 to intersect the second multi-channel active region 210.

The second gate insulating layer 230 may be formed on the field insulating layer 105 and the second multi-channel active region 210. The second gate insulating layer 230 may be formed on the upper surface of the field insulating layer 105 and along the profile of the second multi-channel active region 210.

The second interfacial layer 231 may be formed on the second multi-channel active region 210. The second interfacial layer 231 may be formed along the profile of the second multi-channel active region 210 protruding from the top surface of the field insulating layer 105. Although the second interfacial layer 231 is shown as being not formed on the upper surface of the field insulating layer 105, it is not limiting.

The second high-k insulating layer 232 may be formed on the second interfacial layer 231 and along the profile of the second multi-channel active region 210 and the upper surface of the field insulating layer 105.

The second gate electrode structure 220 is formed on the second gate insulating layer 230 and may intersect the second multi-channel active region 210. That is, each of the second lower conductive layer 221, the second etch-stop conductive layer 222, the second p-type work function tuning layer 223, the second n-type work function tuning layer 224, the second barrier conductive layer 225, and the second filling conductive layer 228 may intersect the second multi-channel active region 210.

Each of the second lower conductive layer 221, the second etch-stop conductive layer 222, the second p-type work function tuning layer 223, the second n-type work function tuning layer 224, and the second barrier conductive layer 225 may include a portion formed along the profile of the second multi-channel active region 210 protruding from the upper surface of the field insulating layer 105 and a portion extending along the upper surface of the field insulating layer 105.

The second source/drain region 245 may be formed in the second multi-channel active region 210. The second source/drain region 245 may comprise an epitaxial layer formed in the second multi-channel active region 210 or on the second multi-channel active region 210.

Although FIG. 18 depicts the first gate electrode structure 120 and the second gate electrode structure 220 are similar to the first gate electrode structure 120 and the second gate electrode structure 220 of FIG. 11, this is not limiting.

The first gate electrode structure 120 and the second gate electrode structure 220 may be similar to the first gate electrode structure 120 and the second gate electrode structure 220 described above with respect to FIGS. 12 to 15.

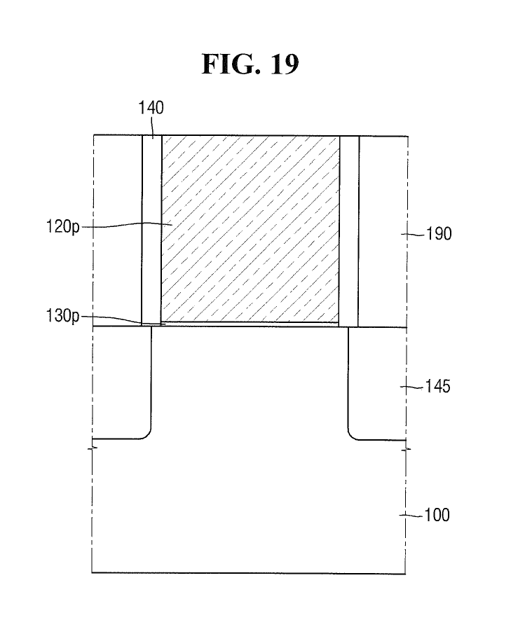

FIGS. 19 to 24 are cross-sectional views for illustrating processing steps of a method for fabricating a semiconductor device according to some exemplary embodiments of the present inventive concept.

Referring to FIG. 19, a dummy gate insulating layer 130p and a dummy gate electrode 120p may be sequentially stacked on a substrate 100.

The dummy gate insulating layer 130p may include silicon oxide, silicon oxynitride, and combinations thereof. The dummy gate electrode 120p may be, for example, silicon, and more specifically may include one of polycrystalline silicon (poly Si), amorphous silicon (a-Si), and combinations thereof. The dummy gate electrode 120p may or may not be doped with an impurity.

On a sidewall of the dummy gate electrode 120p, a first gate spacer 140 may be formed. After the first gate spacer 140 is formed, a first source/drain region 145 adjacent to the dummy gate electrode 120p may be formed.

On the substrate 100, an interlayer insulating layer 190 covering the dummy gate electrode 120p may be formed. By forming the interlayer insulating layer 190 flat, the upper surface of the dummy gate electrode 120p and the first gate spacer 140 may be exposed.

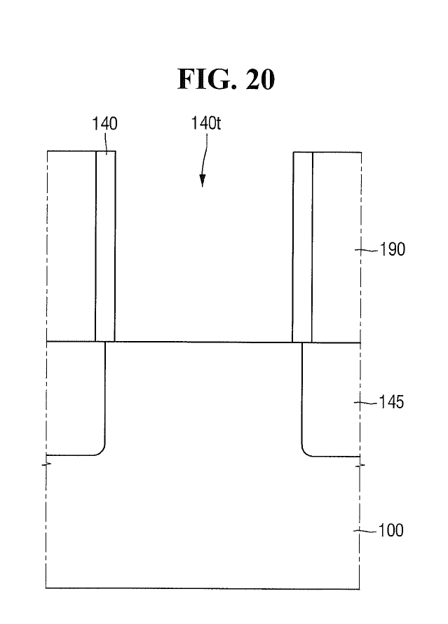

Referring to FIG. 20, the dummy gate insulating layer 130p and the dummy gate electrode 120p may be removed. By removing the dummy gate insulating layer 130p and the dummy gate electrode 120p, a first trench 140t may be formed.

The interlayer insulating layer 190 may include the first trench 140t defined by the first gate spacer 140.

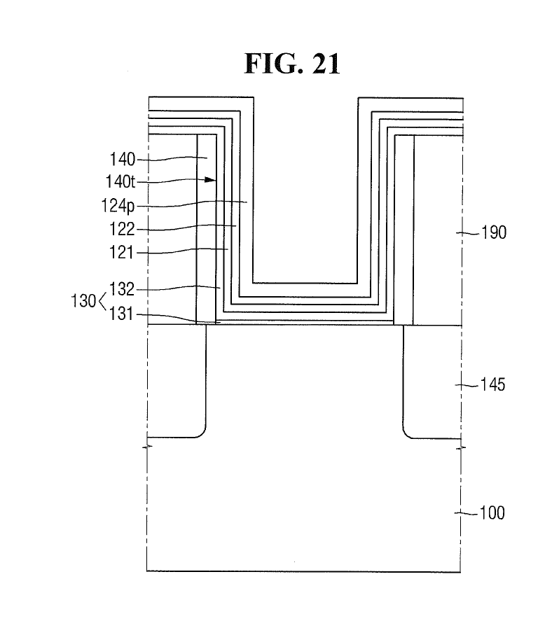

Referring to FIG. 21, a first gate insulating layer 130 may be formed on the substrate 100. The first gate insulating layer 130 may be formed on the sidewalls and the bottom surface of the first trench 140t and the upper surface of the interlayer insulating layer 190.

A first interfacial layer 131 may be formed on the bottom surface of the first trench 140t. The first high-k insulating layer 132 may be formed on the first interfacial layer 131. The first high-k insulating layer 132 may be formed on the sidewalls and the bottom surface of the first trench 140t and the upper surface of the interlayer insulating layer 190.

The first lower conductive layer 121 may be formed on the first gate insulating layer 130. The first lower conductive layer 121 may be formed on the sidewalls and the bottom surface of the first trench 140t and the upper surface of the interlayer insulating layer 190. The first lower conductive layer 121 may be formed along the profile of the first gate insulating layer 130.

The first etch-stop conductive layer 122 may be formed on the first lower conductive layer 121. The first etch-stop conductive layer 122 may be formed on the sidewalls and the bottom surface of the first trench 140t and the upper surface of the interlayer insulating layer 190. The first etch-stop conductive layer 122 may be formed along the profile of the first lower conductive layer 121.

A preliminary n-type work function tuning layer 124p may be formed on the first etch-stop conductive layer 122. The preliminary n-type work function tuning layer 124p may be formed on the sidewalls and the bottom surface of the first trench 140t and the upper surface of the interlayer insulating layer 190. The preliminary n-type work function tuning layer 124p may be formed along the profile of the first etch-stop conductive layer 122.

The preliminary n-type work function tuning layer 124p may include one of TiAl, TiAlN, TiAlC and TiAlCN, for example. In an embodiment, the first n-type work function tuning layer 124 may include one of the above-described materials in which Ti is substituted with Ta, W, Ru, Nb, Mo, Hf or La.

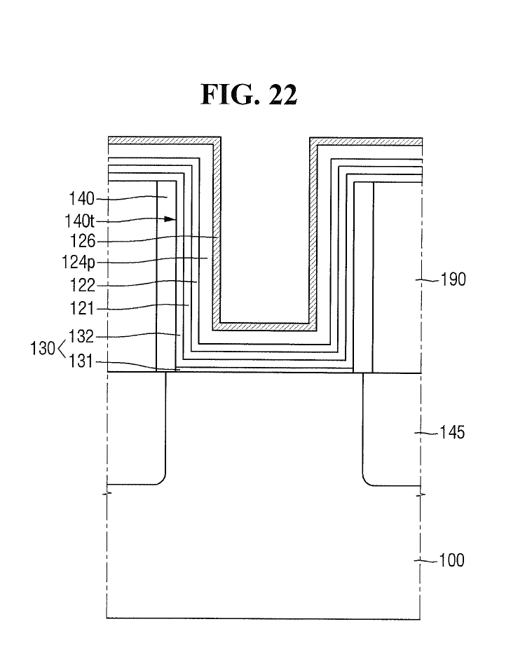

Referring to FIG. 22, a first lower barrier conductive layer 126 may be formed on the preliminary n-type work function tuning layer 124p.

The first lower barrier conductive layer 126 and the preliminary n-type work function tuning layer 124p may be formed, for example, in situ. The first lower barrier conductive layer 126 may be in contact with the preliminary n-type work function tuning layer 124.

The first lower barrier conductive layer 126 may be formed on the sidewalls and the bottom surface of the first trench 140t and the upper surface of the interlayer insulating layer 190. The first lower barrier conductive layer 126 may be formed along the profile of the preliminary n-type work function tuning layer 124p.

Referring to FIG. 23, a film treatment process 50 may be carried out on the preliminary n-type work function tuning layer 124p. For example, the film treatment process 50 may include at least one of a plasma treatment process, an annealing process, and an UV (ultra violet ray) process.

Through the film treatment process 50, the preliminary n-type work function tuning layer 124p may be changed into the first n-type work function tuning layer 124. Through the film treatment process 50, the resistance of the preliminary n-type work function tuning layer 124p can be reduced.

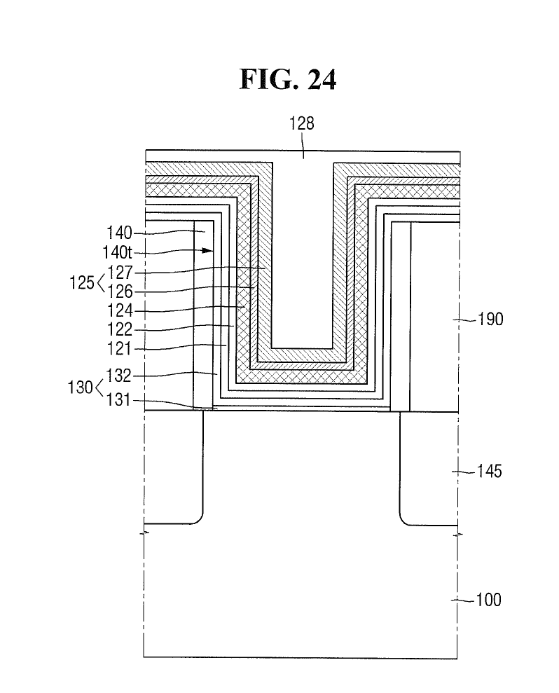

Referring to FIG. 24, the first upper barrier conductive layer 127 may be formed on the first lower barrier conductive layer 126.

The first upper barrier conductive layer 127 may be formed on the sidewalls and the bottom surface of the first trench 140t and the upper surface of the interlayer insulating layer 190. The first upper barrier conductive layer 127 may be formed along the profile of the first lower barrier conductive layer 126.

During the film treatment process 50, the crystal structure or crystal arrangement of the surface of the first lower barrier conductive layer 126 may be changed. As a result, a boundary may be formed between the first lower barrier conductive layer 126 and the first upper barrier conductive layer 127.

The first barrier conductive layer 125 including the first lower barrier conductive layer 126 and the first upper barrier conductive layer 127 may be formed on the first n-type work function tuning layer 124.

The first filling conductive layer 128 may be formed on the first upper barrier conductive layer 127. The first filling conductive layer 128 may be used to fill the first trench 140t and may cover the first upper barrier conductive layer 127 on the upper surface of the interlayer insulating layer 190.

Subsequently, the first high-k insulating layer 132, the first lower conductive layer 121, the first etch-stop conductive layer 122, the first n-type work function tuning layer 124 and the first barrier conductive layer 125 formed on the upper surface of the interlayer insulating layer 190 may be removed.

FIGS. 19 to 24 illustrate a method for fabricating a semiconductor device performed in an area. It is to be understood that the method for fabricating a semiconductor device described with reference to FIGS. 19 to 24 may be performed in other areas, e.g., the first area I and the second area II as well (see e.g., FIG. 6). In an embodiment, it is to be understood that the film treatment process 50 may be performed in the first area I but not in the second area II (see e.g., FIG. 23).

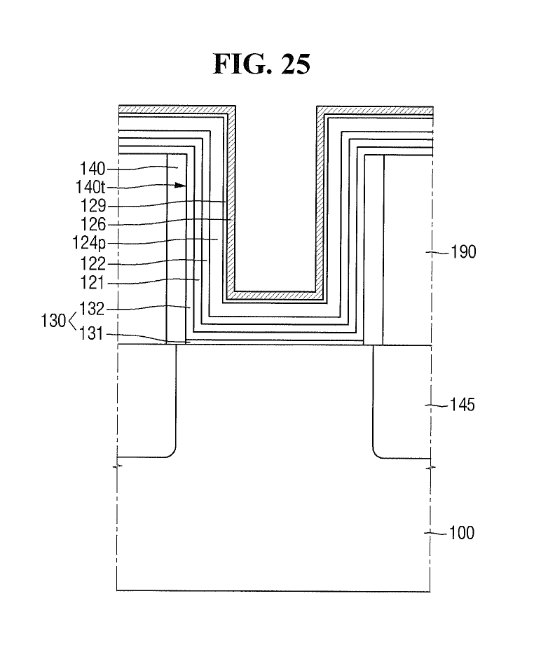

FIG. 25 is a diagram showing a processing step of the method according to some embodiments of the present inventive concept. The processing step shown in FIG. 25 may be performed after the step shown in FIG. 22.

Referring to FIG. 25, a part of the preliminary n-type work function tuning layer 124p may be oxidized such that the inserted insulating layer 129 may be formed on the preliminary n-type work function tuning layer 124p. The inserted insulating layer 129 may be formed on the surface of the preliminary n-type work function tuning layer 124p.

The first lower barrier conductive layer 126 may be formed on the inserted insulating layer. The first lower barrier conductive layer 126 and the preliminary n-type work function tuning layer 124p may be formed, for example, ex-situ. The first lower barrier conductive layer 126 may be in contact with the inserted insulating layer 129.

Subsequently, referring to FIG. 24, the film treatment process 50 may be carried out on the preliminary n-type work function tuning layer 124p.

During the film treatment process 50, the oxygen comprised in the inserted insulating layer 129 may escape through the first lower barrier conductive layer 126. During the film treatment process 50, the inserted insulating layer 129 formed on the surface of the preliminary n-type work function tuning layer 124p can be removed.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims. It is therefore desired that the present embodiments be considered in all respects as illustrative and not restrictive, reference being made to the appended claims rather than the foregoing description to indicate the scope of the invention.

In the claims:

1. A semiconductor device comprising:
a gate insulating layer on a substrate;
a first work function tuning layer on the gate insulating layer;
a lower barrier conductive layer on and in contact with the first work function tuning layer; and
an upper barrier conductive layer on and in contact with the lower barrier conductive layer, wherein the upper barrier conductive layer and the lower barrier conductive layer comprise a common material.

2. The semiconductor device of claim 1, wherein the lower barrier conductive layer and the upper barrier conductive layer each comprise a titanium nitride (TiN) layer.

3. The semiconductor device of claim 1, wherein the first work function tuning layer comprises an n-type work function tuning layer.

4. The semiconductor device of claim 3, wherein the first work function tuning layer comprises a titanium aluminum carbide (TiAlC) layer.

5. The semiconductor device of claim 1, further comprising a second work function tuning layer between the first work function tuning layer and the gate insulating layer.

6. The semiconductor device of claim 5, wherein the second work function tuning layer comprises a TiN layer.

7. The semiconductor device of claim 5, wherein the second work function tuning layer is in contact with the gate insulating layer.

8. The semiconductor device of claim 1, further comprising a lower TiN layer and an etch-stop conductive layer stacked on the gate insulating layer between the gate insulating layer and the first work function tuning layer.

9. The semiconductor device of claim 8, wherein the first work function tuning layer is in contact with the etch-stop conductive layer.

10. The semiconductor device of claim 8, further comprising a second work function tuning layer between the etch-stop conductive layer and the first work function tuning layer.

11. The semiconductor device of claim 1, further comprising an interlayer insulating layer having a trench therein and disposed on the substrate, wherein the gate insulating layer extends along side walls and a bottom surface of the trench.

12. The semiconductor device of claim 1, further comprising a multi-channel active region on the substrate, wherein the first work function tuning layer, the lower barrier conductive layer and the upper barrier conductive layer intersect the multi-channel active region.

13. A semiconductor device comprising:
an interlayer insulating layer on a substrate and defining a first trench and a second trench;
an n-type first work function tuning layer extending along sidewalls and a bottom surface of the first trench;
a first lower barrier conductive layer on and in contact with the first work function tuning layer;
a first upper barrier conductive layer on and in contact with the first lower barrier conductive layer, wherein the first upper barrier conductive layer and the first lower barrier conductive layer comprise a first material in common;
a second work function tuning layer extending along side walls and a bottom surface of the second trench, wherein the second work function tuning layer and the first work function tuning layer comprise a second material in common; and
a second barrier conductive layer on the second work function tuning layer, wherein the second barrier conductive layer and the first lower barrier conductive layer comprise a third material in common, wherein a thickness of the second barrier conductive layer is greater than a thickness of the first lower barrier conductive layer and greater than a thickness of the first upper barrier conductive layer.

14. The semiconductor device of claim 13, wherein the thickness of the second barrier conductive layer is substantially equal to a sum of the thickness of the first lower barrier conductive layer and the thickness of the first upper barrier conductive layer.

15. The semiconductor device of claim 13, wherein the first lower barrier conductive layer, the first upper barrier conductive layer and the second barrier conductive layer each comprise a TiN layer.

16. The semiconductor device of claim 13, wherein the first work function tuning layer and the second work function tuning layer each comprise a TiAlC layer.

17. The semiconductor device of claim 13, wherein the second barrier conductive layer is in contact with the second work function tuning layer.

18. The semiconductor device of claim 13, further comprising an inserted insulating layer between the second work function tuning layer and the second barrier conductive layer and comprising an oxide included in the second work function tuning layer.

19. The semiconductor device of claim 13, further comprising:
a first filling conductive layer in the first trench on the first upper barrier conductive layer; and
a second filling conductive layer in the second trench on the second barrier conductive layer,
wherein the first filling conductive layer and the second filling conductive layer comprise a third material in common.

20. The semiconductor device of claim 13, wherein the first trench is formed in an NMOS transistor region and wherein the second trench is formed in a PMOS transistor region.

21. The semiconductor device of claim 13, wherein a width of the first trench is less than a width of the second trench.

22. The semiconductor device of claim 13, further comprising:
a first fin-shaped pattern and a second fin-shaped pattern protruding from the substrate,
wherein the first trench intersects the first fin-shaped pattern and the second trench intersects the second fin-shaped pattern.

23. A semiconductor device comprising:
a fin-shaped pattern protruding from a substrate;
a field insulating layer on the substrate and covering a part of a side wall of the fin-shaped pattern;
a gate insulating layer on an upper surface of the field insulating layer and the fin-shaped pattern;
a TiAlC layer on the gate insulating layer;
a first TiN layer on and in contact with the TiAlC layer; and
a second TiN layer on and in contact with the first TiN layer.

24. The semiconductor device of claim 23, further comprising a third TiN layer and a TaN layer stacked on the gate insulating layer between the gate insulating layer and the TiAlC layer.

25. The semiconductor device of claim 24, wherein the TaN layer is in contact with the TiAlC layer.

26. The semiconductor device of claim 24, further comprising a work function tuning layer between the TaN layer and the TiAlC layer and comprising a TiN layer.

27. The semiconductor device of claim 23, further comprising a work function tuning layer between the gate insulating layer and the TiAlC layer and comprising a TiN layer.

28-33. (canceled)
